(19) United States
(12) Patent Application Publication
(10) Pub. No.: US 2026/0004741 A1
(43) Pub. Date: Jan. 1, 2026

(54) DISPLAY DEVICE

(71) Applicant: Samsung Display Co., Ltd., Yongin-si (KR)

(72) Inventors: SUNHO KIM, Yongin-si (KR); JAEWOO LEE, Yongin-si (KR); YOOMIN KO, Yongin-si (KR); JUCHAN PARK, Yongin-si (KR); CHUNG SOCK CHOI, Yongin-si (KR)

(21) Appl. No.: 19/246,917

(22) Filed: Jun. 24, 2025

(30) Foreign Application Priority Data
Jun. 28, 2024 (KR) 10-2024-0085608

(51) Int. Cl. G09G 3/3266

(52) U.S. Cl. CPC G09G 3/3266; G09G 2300/0426; G09G 2310/08; G09G 2330/021

(57) ABSTRACT

A display device includes a base layer in which a display region and a non-display region adjacent to the display region are defined; a circuit layer including a scan clock line in the non-display region and extending in a first direction, and a scan driver connected to the scan clock line; and a light-emitting element on the circuit layer, and including a first electrode, an intermediate layer on the first electrode, and a second electrode on the intermediate layer, wherein a first opening overlapping the scan clock line is defined in the second electrode.

### CROSS-REFERENCE TO RELATED APPLICATION

The present application claims priority to and the benefit of Korean Patent Application No. 10-2024-0085608, filed on Jun. 28, 2024, in the Korean Intellectual Property Office, the entire disclosure of which is incorporated herein by reference.

### BACKGROUND

The present disclosure herein relates to a display device, and more particularly, to a display device with improved reliability.

Display devices include a plurality of pixels and a driving circuit (e.g., scan driving circuit and data driving circuit) that controls the plurality of pixels. The plurality of pixels each include a display element and a pixel driving circuit which controls the display element. The pixel driving circuit may include a plurality of transistors which are organically connected to each other.

As the size and resolution of a display device increase, the number of signal lines and connection electrodes, which connect the transistor and the display element that are included in the pixels, increase, and a degree of integration of the driving circuit included in the pixels increases.

The above information disclosed in this Background section is only for enhancement of understanding of the background of the invention and therefore it may contain information that does not form.

### SUMMARY

Aspect of embodiments of the present disclosure are directed to a display device with reduced power consumption.

According to some embodiments of the present disclosure, there is provided a display device including: a base layer in which a display region and a non-display 1 region adjacent to the display region are defined; a circuit layer including a scan clock line in the non-display region and extending in a first direction, and a scan driver connected to the scan clock line; and a light-emitting element on the circuit layer, and including a first electrode, an intermediate layer on the first electrode, and a second electrode on the intermediate layer, wherein a first opening overlapping the scan clock line is defined in the second electrode.

In some embodiments, the second electrode includes a first sub-electrode and a second sub-electrode that are spaced apart from each other with respect to the first opening.

In some embodiments, the display device further includes a connection electrode configured to electrically connect the first sub-electrode and the second sub-electrode to each other, wherein the first sub-electrode and the second sub-electrode each are in contact with the connection electrode.

In some embodiments, the display device further includes: an insulation film in which a contact opening that exposes at least a portion of the connection electrode is defined; and a separator in the contact opening.

In some embodiments, the contact opening includes a first contact opening and a second contact opening that are spaced apart from each other with respect to the opening, and the separator includes a first separator in the first contact opening, and a second separator in the second contact opening.

In some embodiments, in a first contact region adjacent to the first separator, a lower surface of the first sub-electrode is in contact with an upper surface of the connection electrode, and in a second contact region adjacent to the second separator, a lower surface of the second sub-electrode is in contact with an upper surface of the connection electrode.

In some embodiments, the first separator and the second separator each are provided in plural form, and the first separators and the second separators are each arranged in the first direction.

In some embodiments, the connection electrode and the first electrode are on a same layer.

In some embodiments, the circuit layer further includes an emission clock line in the non-display region and extending in the first direction, and an emission driver connected to the emission clock line.

In some embodiments, a second opening overlapping the emission clock line is defined in the second electrode, and the first opening and the second opening are spaced apart from each other in a second direction crossing the first direction.

In some embodiments, the emission driver and the scan driver are spaced apart from each other with respect to the display region.

In some embodiments, the display device further includes an insulation layer in each of the first opening and the second opening.

In some embodiments, the display device further includes a power supply line in the non-display region, and configured to apply a driving voltage to the second electrode.

In some embodiments, the non-display region includes a first non-display region in which the power supply line is, and a second non-display region in which the first opening is positioned, and the second non-display region is between the first non-display region and the display region.

According to some embodiments of the present disclosure, there is provided a display device including: a circuit layer including a scan clock line configured to apply a clock signal and a scan driver connected to the scan clock line; a light-emitting element on the circuit layer, and including a first electrode, an intermediate layer on the first electrode, and a second electrode having a first sub-electrode and a second sub-electrode spaced apart from each other with respect to an opening that is defined overlapping the scan clock line; and a connection electrode configured to electrically connect the first sub-electrode and the second sub-electrode to each other, wherein the connection electrode and the first electrode are on a same layer.

In some embodiments, the display device further includes: an insulation film in which a contact opening that exposes at least a portion of the connection electrode is defined; and a separator in the contact opening.

In some embodiments, the contact opening includes a first contact opening and a second contact opening which are spaced apart from each other with respect to the opening, and the separator includes a first separator in the first contact opening, and a second separator in the second contact opening.

In some embodiments, in a first contact region adjacent to the first separator, a lower surface of the first sub-electrode is in contact with an upper surface of the connection electrode, and in a second contact region adjacent to the second separator, a lower surface of the second sub-electrode is in contact with an upper surface of the connection electrode.

In some embodiments, the display device further includes an insulation layer in the opening.

In some embodiments, the scan clock line extends in a first direction, and the opening is defined to be parallel to the scan clock line in the first direction.

According to some embodiments of the present disclosure, there is provided an electronic device including: a display device configured to display an image; and a processor configured to control the display device to display the image, wherein the display device includes: a base layer in which a display region and a non-display region adjacent to the display region are defined; a circuit layer including a scan clock line in the non-display region and extending in a first direction, and a scan driver connected to the scan clock line; and a light-emitting element on the circuit layer, and including a first electrode, an intermediate layer on the first electrode, and a second electrode on the intermediate layer, wherein a first opening overlapping the scan clock line is defined in the second electrode.

In some embodiments, the second electrode includes a first sub-electrode and a second sub-electrode that are spaced apart from each other with respect to the first opening.

In some embodiments, the electronic device further includes a connection electrode configured to electrically connect the first sub-electrode and the second sub-electrode to each other, wherein the first sub-electrode and the second sub-electrode each are in contact with the connection electrode.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view illustrating a display device according to some embodiments of the inventive concept;

FIG. 2 is an exploded perspective view illustrating a display device according to some embodiments of the inventive concept;

FIG. 3 is a cross-sectional view of a display panel according to some embodiments of the inventive concept;

FIG. 4 is a plan view of a display panel according to some embodiments of the inventive concept;

FIG. 5 illustrates an equivalent circuit diagram of a pixel according to some embodiments of the inventive concept;

FIG. 6 is a cross-sectional view of the display panel taken along the line I-I′ of FIG. 4, according to some embodiments of the inventive concept;

FIG. 7 is an enlarged view of the region AA′ illustrated in FIG. 4, according to some embodiments of the inventive concept;

FIG. 8A is a cross-sectional view of the display panel taken along the line II-II′ of FIG. 7, according to some embodiments of the inventive concept;

FIG. 8B is a cross-sectional view of the display panel taken along the line III-III′ of FIG. 7, according to some embodiments of the inventive concept;

FIG. 8C is an enlarged view of the region BB′ illustrated in FIG. 7, according to some embodiments of the inventive concept;

FIG. 8D is a cross-sectional view of a display panel according to some other embodiments of the inventive concept;

FIGS. 9A and 9B are enlarged views of a portion of a display panel according to some embodiments of the inventive concept;

FIG. 10A is a cross-sectional view of the display panel taken along the line IV-IV′ of FIG. 9A, according to some embodiments of the inventive concept;

FIG. 10B is a cross-sectional view of the display panel taken along the line V-V′ of FIG. 9A, according to some embodiments of the inventive concept; and

FIG. 11 is a block diagram illustrating an electronic device according to some embodiments of the inventive concept.

### DETAILED DESCRIPTION

The inventive concept may be implemented in various modifications and have various forms, and specific embodiments are illustrated in the drawings and described in detail in the text. It is to be understood, however, that the inventive concept is not intended to be limited to the particular forms disclosed, but on the contrary, is intended to cover all modifications, equivalents, and alternatives falling within the spirit and scope of the invention.

In this specification, it will be understood that when an element (or a region, a layer, a portion, or the like) is referred to as being “on”, “connected to” or “coupled to” another element, it can be directly disposed on/connected to/coupled to the other element or layer or intervening elements may be disposed therebetween.

Like numbers or symbols refer to like elements throughout. Also, in the drawings, the thicknesses, ratios, and dimensions of the elements are exaggerated for effective description of the technical contents.

The term “and/or” includes all of one or more combinations which can be defined by related elements.

Although the terms first, second, etc. may be used to describe various elements, these elements should not be limited by these terms. These terms are only used to distinguish one element from another element. For example, a first element may be referred to as a second element, and similarly, a second element may also be referred to as a first element without departing from the scope of the present disclosure. The singular forms include the plural forms as well, unless the context clearly indicates otherwise.

Also, terms of “below”, “on lower side”, “above”, “on upper side”, or the like may be used to describe the relationships of the elements illustrated in the drawings. These terms have relative concepts and are described on the basis of the directions indicated in the drawings.

Unless otherwise defined, all terms (including technical and scientific terms) used herein have the same meaning as commonly understood by one of ordinary skills in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

Hereinafter, embodiments of the inventive concept will be described with reference to the accompanying drawings.

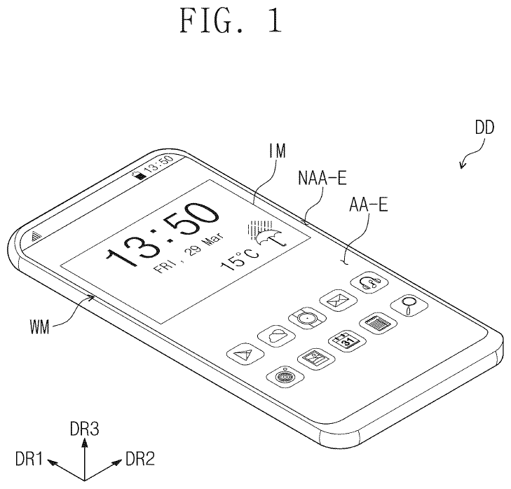

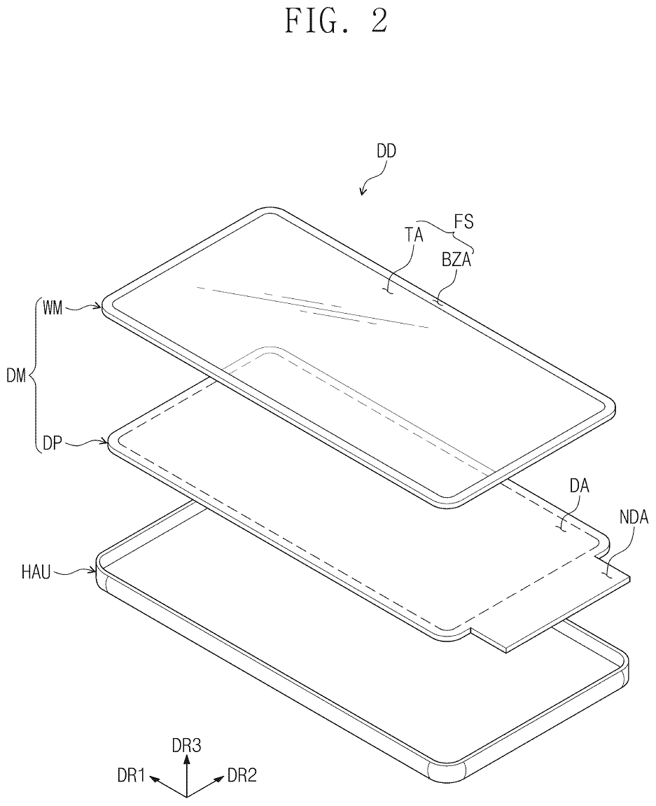

FIG. 1 is a perspective view illustrating a display device according to some embodiments of the inventive concept. FIG. 2 is an exploded perspective view illustrating a display device according to some embodiments of the inventive concept.

A display device DD may display an image IM through an active region AA-E. The active region AA-E may include a plane defined by a first direction DR1 and a second direction DR2 crossing the first direction DR1. A peripheral region NAA-E is adjacent to the active region AA-E. The peripheral region NAA-E may surround the active region AA-E. However, the peripheral region NAA-E may be disposed adjacent to only one side of the active region AA-E, or may be omitted.

The display device DD according to some embodiments may include a housing HAU and a display module DM. The display module DM according to some embodiments may include a display panel DP and a window member WM.

The window member WM may cover the entire exterior of the display module DM. The window member WM may include a transmissive region TA and a bezel region BZA. A front surface of the window member WM including the transmissive region TA and the bezel region BZA may correspond to a front surface of the display device DD. The transmissive region TA may correspond to the active region AA-E of the display device DD illustrated in FIG. 1, and the bezel region BZA may correspond to the peripheral region NAA-E of the display device DD illustrated in FIG. 1.

The transmissive region TA may be an optically transparent region. The bezel region BZA may be a region having a relatively lower light transmittance than the transmissive region TA. The bezel region BZA may have a set or predetermined color. The bezel region BZA may be adjacent to the transmissive region TA, and may surround the transmissive region TA. However, the bezel region BZA may be disposed adjacent to only one side of the transmissive region TA, and a portion thereof may be omitted.

The display panel DP may include a display region DA and a non-display region NDA around the display region DA. The display region DA may be activated in response to an electrical signal. In some embodiments, the display region DA may be a region in which the image IM (see, e.g., FIG. 1) is displayed. The display region DA of the display panel DP may correspond to the active region AA-E of the display device DD illustrated in FIG. 1, and the non-display region NDA of the display panel DP may correspond to the peripheral region NAA-E of the display device DD illustrated in FIG. 1. The transmissive region TA may overlap at least a portion of the display region DA. The non-display region NDA may be a region covered by the bezel region BZA.

An input sensing unit may be provided on the display panel DP. The input sensing unit may sense an external input applied from the outside. The external input may be a user's input. The user's input may include various types of external inputs such as a part of the user body, light, heat, a pen, or pressure. The input sensing unit may be directly disposed on the display panel DP, or may be coupled to the display panel DP through an additional adhesive member.

In this specification, it will be understood that when one component (or region, layer, portion, etc.) is referred to as being “directly disposed” on another component, no other component is disposed between the one component and the other component. That is, the wording, one component being “directly disposed” on another component means that the one component is “in contact” with the other component.

The housing HAU may accommodate the display panel DP, and the like. The housing HAU may be coupled to the window member WM.

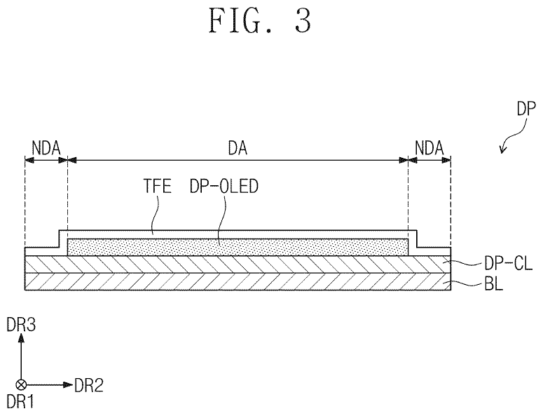

FIG. 3 is a cross-sectional view of a display panel according to some embodiments of the inventive concept. FIG. 3 exemplarily illustrates a cross section of a display panel DP as viewed from the first direction DR1.

Referring to FIG. 3, the display panel DP may include a base layer BL, a circuit layer DP-CL disposed on the base layer BL, a display element layer DP-OLED disposed on the circuit layer DP-CL, and an encapsulation layer TFE disposed on the display element layer DP-OLED. The display panel DP may include a display region DA and a non-display region NDA around the display region DA.

The base layer BL may include a flexible plastic material such as polyimide (PI). The display element layer DP-OLED may be disposed on the display region DA.

A plurality of pixels may be disposed on the circuit layer DP-CL and the display element layer DP-OLED. The pixels may each include transistors disposed on the circuit layer DP-CL and a light-emitting element disposed in the display element layer DP-OLED and connected to the transistors. A configuration of the pixel will be described in further detail below.

The encapsulation layer TFE may be disposed on the circuit layer DP-CL so as to cover the display element layer DP-OLED. The encapsulation layer TFE may protect the pixels from moisture, oxygen, and foreign matters.

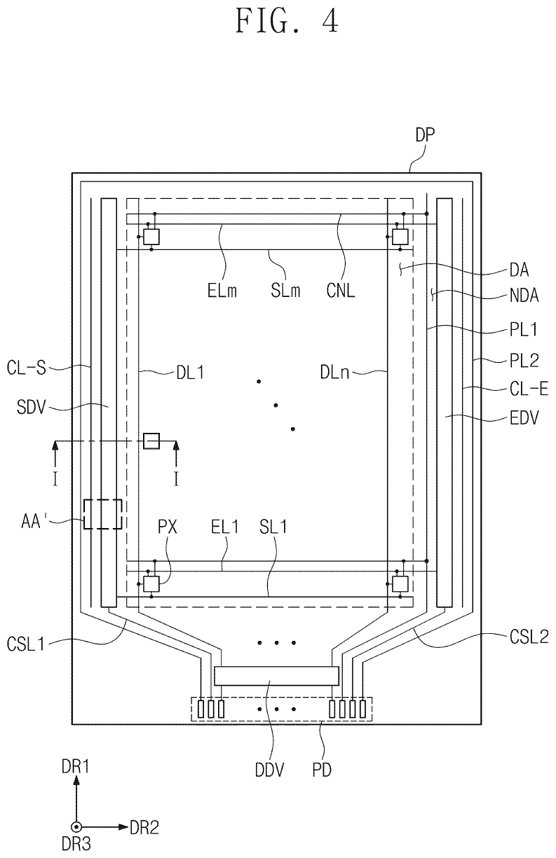

FIG. 4 is a plan view of a display panel according to some embodiments of the inventive concept.

Referring to FIG. 4, a display panel DP may include a scan driver SDV, a data driving unit DDV, an emission driver EDV, and a plurality of pads PD. The display panel DP may have a rectangular shape having long sides extending in the first direction DR1 and short sides extending in the second direction DR2, but the shape of the display panel DP is not limited thereto. The display panel DP may include a display region DA and a non-display region NDA surrounding the display region DA.

The display panel DP may include a plurality of pixels PX, a plurality of scan lines SL1 to SLm, a scan clock line CL-S, a plurality of data lines DL1 to DLn, a plurality of emission lines EL1 to ELm, an emission clock line CL-E, first and second control lines CSL1 and CSL2, first and second power supply lines PL1 and PL2, and connection lines CNL. As used herein, m and n are natural numbers.

The pixels PX may be disposed in the display region DA. The scan driver SDV and the emission driver EDV may be disposed in the non-display region NDA adjacent to the respective long sides of the display panel DP. The data driving unit DDV may be disposed in the non-display region NDA adjacent to one short side among the short sides of the display panel DP. When viewed in a plan view (e.g., along the third direction DR3), the data driving unit DDV may be adjacent to a lower end of the display panel DP.

The scan clock line CL-S may extend in the first direction DR1 to be connected to the scan driver SDV. The scan clock line CL-S may transmit a clock signal, and the like, from a timing controller to the scan driver SDV. FIG. 4 exemplarily illustrates one scan clock line CL-S, but the number of scan clock lines CL-S is not limited thereto and may thus be two or more.

The emission clock line CL-E may extend in the first direction DR1 to be connected to the emission driver EDV. The emission clock line CL-E may transmit a clock signal, and the like, from the timing controller to the emission driver EDV. FIG. 4 exemplarily illustrates one emission clock line CL-E, but the number of the emission clock lines CL-E is not limited thereto and may thus be two or more.

The scan lines SL1 to SLm may extend in the second direction DR2 to be connected to the pixels PX and the scan driver SDV. The data lines DL1 to DLn may extend in the first direction DR1 to be connected to the pixels PX and the data driving unit DDV. The emission lines EL1 to ELm may extend in the second direction DR2 to be connected to the pixels PX and the emission driver EDV.

The first power supply line PL1 may extend in the first direction DR1 and may be disposed in the non-display region NDA. The first power supply line PL1 may be disposed between the display region DA and the emission driver EDV.

The connection lines CNL may extend in the second direction DR2 and may be arranged in the first direction DR1 to be connected to the first power supply line PL1 and the pixels PX. A first voltage may be applied to the pixels PX through the first power supply line PL1 and the connection lines CNL which are connected to each other. Substantially, the connection lines CNL may be defined as a part of the first power supply line PL1 that receives the first voltage.

The second power supply line PL2 may be disposed in the non-display region NDA, and may extend along the long sides of the display panel DP and the other short side of the display panel DP in which the data driving unit DDV is not disposed. The second power supply line PL2 may be disposed outside the scan driver SDV and the emission driver EDV.

The second power supply line PL2 may extend toward the display region DA to be connected to the pixels PX. A second voltage, which has a lower voltage level than the first voltage, may be applied to the pixels PX through the second power supply line PL2.

The first control line CSL1 may be connected to the scan driver SDV, and may extend toward the lower end of the display panel DP. The second control line CSL2 may be connected to the emission driver EDV, and may extend toward the lower end of the display panel DP. The data driving unit DDV may be disposed between the first control line CSL1 and the second control line CSL2.

The pads PD may be disposed in the non-display region NDA adjacent to the lower end of the display panel DP, and may be more adjacent to the lower end of the display panel DP than the data driving unit DDV. The data driving unit DDV, the first and second power supply lines PL1 and PL2, and the first and second control lines CSL1 and CSL2 may be connected to the pads PD. The data lines DL1 to DLn may be connected to the data driving unit DDV, and the data driving unit DDV may be connected to the pads PD corresponding to the data lines DL1 to DLn.

The display device DD may further include a timing controller for controlling operations of the scan driver SDV, the data driving unit DDV, and the emission driver EDV, and a voltage generator for generating the first and second voltages. The timing controller and the voltage generator may be connected to the corresponding pads through a printed circuit board.

The scan driver SDV may generate a plurality of scan signals, and the scan signals may be applied to the pixels PX through the scan lines SL1 to SLm. The data driving unit DDV may generate a plurality of data voltages, and the data voltages may be applied to the pixels PX through the data lines DL1 to DLn. The emission driver EDV may generate a plurality of light-emitting signals, and the light-emitting signals may be applied to the pixels PX through the emission lines EL1 to ELm.

The pixels PX may receive the data voltages in response to the scan signals. The pixels PX may, in response to the light-emitting signals, emit light with luminance corresponding to the data voltages, and thus display an image.

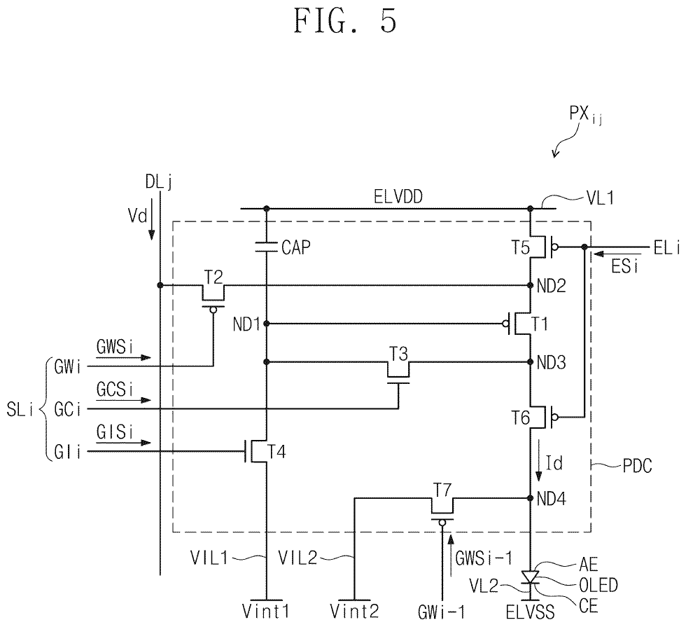

FIG. 5 illustrates an equivalent circuit diagram of a pixel according to some embodiments of the inventive concept. FIG. 5 exemplarily illustrates a pixel PXij that is connected to an i-th scan line SLi, an i-th emission line ELi, and a j-th data line DLj. Here, i and j represent natural numbers.

Referring to FIG. 5, the pixel PXij may include a light-emitting element OLED and a pixel driving circuit PDC electrically connected to the light-emitting element OLED. The pixel driving circuit PDC may include transistors T1 to T7 and a capacitor CAP. The transistors T1 to T7 and the capacitor CAP may control an amount of current flowing through the light-emitting element OLED, and the light-emitting element OLED may generate light having a set or predetermined luminance according to the amount of current provided.

The i-th scan line SLi may include i-th first to third scan lines GWi, GCi, and Gli. The first scan line GWi receiving an i-th write scan signal GWSi may be defined as a write scan line GWi. The second scan line GCi receiving an i-th compensation scan signal GCSi may be defined as a compensation scan line GCi. The third scan line Gli receiving an i-th initialization scan signal GISi may be defined as an initialization scan line Gli.

The transistors T1 to T7 may include first to seventh transistors T1 to T7. The first to seventh transistors T1 to T7 may each include a source electrode, a drain electrode, and a gate electrode. Hereinafter, the source electrode will be referred to as a source, the drain electrode will be referred to as a drain, and the gate electrode will be referred to as a gate.

In this specification, an electrical connection (or linkage) between a transistor and a signal line or between a transistor and another transistor may refer to an electrode of the transistor and the signal line havinge an integrated shape, or being connected via a connection electrode.

The first to seventh transistors T1 to T7 may each be a transistor having an oxide semiconductor layer, or a transistor having a low-temperature polycrystalline silicon (LTPS) semiconductor layer. The first to seventh transistors T1 to T7 may be N-type transistors or P-type transistors. For example, the first, second, fifth, sixth, and seventh transistors T1, T2, T5, T6, and T7 may be PMOS transistors having a LTPS semiconductor layer, and the third and fourth transistors T3 and T4 may be NMOS transistors having an oxide semiconductor layer. However, examples of the transistors T1 to T7 are not limited thereto. In addition, it is exemplarily illustrated that the pixel driving circuit PDC includes seven transistors T1 to T7, but the number of the transistors included in the pixel driving circuit PDC is not limited thereto.

The light-emitting element OLED may be defined as an organic light-emitting element. The light-emitting element OLED may include a first electrode AE and a second electrode CE. For example, the first electrode AE may be an anode, and the second electrode CE may be a cathode. The first electrode AE of the light-emitting element OLED may be electrically connected to a first voltage line VL1 which receives a first driving voltage ELVDD. The second electrode CE of the light-emitting element OLED may be electrically connected to a second voltage line VL2 that receives a second driving voltage ELVSS. The first voltage line VL1 may correspond to the first power supply line PL1 illustrated in FIG. 4, and the second voltage line VL2 may correspond to the second power supply line PL2 illustrated in FIG. 4.

The first transistor T1 may be electrically connected between the light-emitting element OLED and the first voltage line VL1 which receives the first driving voltage ELVDD. The first transistor T1 may include a source connected to a second node ND2, a drain connected to a third node ND3, and a gate connected to a first node ND1. The first transistor T1 may be turned on (i.e., activated) by a voltage of the first node ND1. The first transistor T1 may receive a data voltage Vd transmitted via the data line DLj according to a switching operation of the second transistor T2, and may provide a driving current Id to the light-emitting element OLED. In some embodiments, the first transistor T1 may be defined as a drive transistor.

The second transistor T2 may be electrically connected between the data line DLj and the first transistor T1. The second transistor T2 may include a source connected to the data line DLj, a drain connected to the second node ND2, and a gate connected to the first scan line GWi. The second transistor T2 and the first transistor T1 may be connected via the second node ND2. The second transistor T2 may be turned on by the write scan signal GWSi applied through the first scan line GWi. The data voltage Vd, which is applied to the data line DLj by the turned-on (i.e., activated) second transistor T2, may be transmitted to the source of the first transistor T1. In some embodiments, the second transistor T2 may be defined as a switching transistor.

The third transistor T3 may be electrically connected between the fourth transistor T4 and the first transistor T1. The third transistor T3 may include a source connected to the first node ND1, a drain connected to the third node ND3, and a gate connected to the second scan line GCi. The third transistor T3 and the first transistor T1 may be connected via the third node ND3. The third transistor T3 may be turned on by the compensation scan signal GCSi applied through the second scan line GCi. The turned-on third transistor T3 may electrically connect the gate of the first transistor T1 to the drain of the first transistor T1, and may connect the first transistor T1 to a diode. In some embodiments, the third transistor T3 may be defined as a compensation transistor.

The fourth transistor T4 may be electrically connected between the third transistor T3 and a first initialization line VIL1, which receives a first initialization voltage Vint1. The fourth transistor T4 may include a source connected to the first initialization line VIL1, a drain connected to the first node ND1, and a gate connected to the third scan line Gli. The fourth transistor T4 may be turned on by the initialization scan signal GISi applied through the third scan line Gli. The first initialization voltage Vint1 may be transmitted to the first node ND1 by the turned-on fourth transistor T4, and the potential of the gate of the first transistor T1 may be initialized by the turned-on fourth transistor T4. In some embodiments, the fourth transistor T4 may be defined as an initialization transistor.

The fifth transistor T5 may be electrically connected between the first transistor T1 and the first voltage line VL1, which receives the first driving voltage ELVDD. The fifth transistor T5 may include a source connected to the first voltage line VL1, a drain connected to the second node ND2, and a gate connected to the emission line ELi.

The sixth transistor T6 may be electrically connected between the first transistor T1 and the light-emitting element OLED. The sixth transistor T6 may include a source connected to the third node ND3, a drain connected to the first electrode AE of the light-emitting element OLED via a fourth node ND4, and a gate connected to the emission line ELi.

The fifth transistor T5 and the sixth transistor T6 may be turned on by a light-emitting signal ESi applied through the emission line ELi. The emission time of the light-emitting element OLED may be controlled by the light-emitting signal ESi. When the fifth transistor T5 and the sixth transistor T6 are turned on, the driving current Id, which corresponds to a voltage difference between the first driving voltage ELVDD and a gate voltage of the gate of the first transistor T1, may be generated, and the driving current Id may be supplied to the light-emitting element OLED through the sixth transistor T6, so that the light-emitting element OLED may emit light. In some 1 embodiments, the fifth transistor T5 and the sixth transistor T6 may be defined as emission-control transistors.

The seventh transistor T7 may be electrically connected between the sixth transistor T6 and a second initialization line VIL2 which receives a second initialization voltage Vint2. The seventh transistor T7 may include a source connected to the fourth node ND4, a drain connected to the second initialization line VIL2, and a gate connected to a first scan line GWi−1. The gate of the seventh transistor T7 may be connected to an (i−1)-th write scan line GWi−1, which is a write scan line at a previous stage of the i-th write scan line GWi. However, some embodiments of the inventive concept is not limited thereto, and the gate of the seventh transistor T7 may be electrically connected to a separate fourth scan line.

The seventh transistor T7 may be turned on by an (i−1)-th write scan signal GWSi−1 applied through the first scan line GWi−1. The second initialization voltage Vint2 may be transmitted to the fourth node ND4 by the turned-on seventh transistor T7. The second initialization voltage Vint2 may have the same voltage level as the first initialization voltage Vint1. However, some embodiments of the inventive concept is not limited thereto, and the second initialization voltage Vint2 may have a different voltage level from the first initialization voltage Vint1. In some embodiments, the seventh transistor T7 may be defined as an initialization transistor.

The seventh transistor T7 may improve black expression capability of the pixel PXij. The seventh transistor T7 may cause a portion of the driving current Id to escape as a bypass current through the seventh transistor T7. A current, which is reduced by the amount of the bypass current escaping through the seventh transistor T7 from the driving current Id, may be provided to the light-emitting element OLED, and thus a black image may be clearly expressed when the black image is displayed. That is, an accurate black luminance image may be achieved through the seventh transistor T7, and thus a contrast ratio of the display device DD (see, e.g., FIG. 1) may be improved (e.g., increase).

The capacitor CAP may include a first electrode receiving the first driving voltage ELVDD and a second electrode connected to the first node ND1. An electric charge, which corresponds to a voltage difference between the first electrode and the second electrode, may be stored in the capacitor CAP. When the fifth transistor T5 and the sixth transistor T6 are turned on, the amount of current flowing through the first transistor T1 may be determined, depending on the voltage stored in the capacitor CAP.

The configuration of the pixel driving circuit PDC illustrated in FIG. 5 is an example. The configuration of the pixel driving circuit PDC is not limited thereto, and may be changed for implementations.

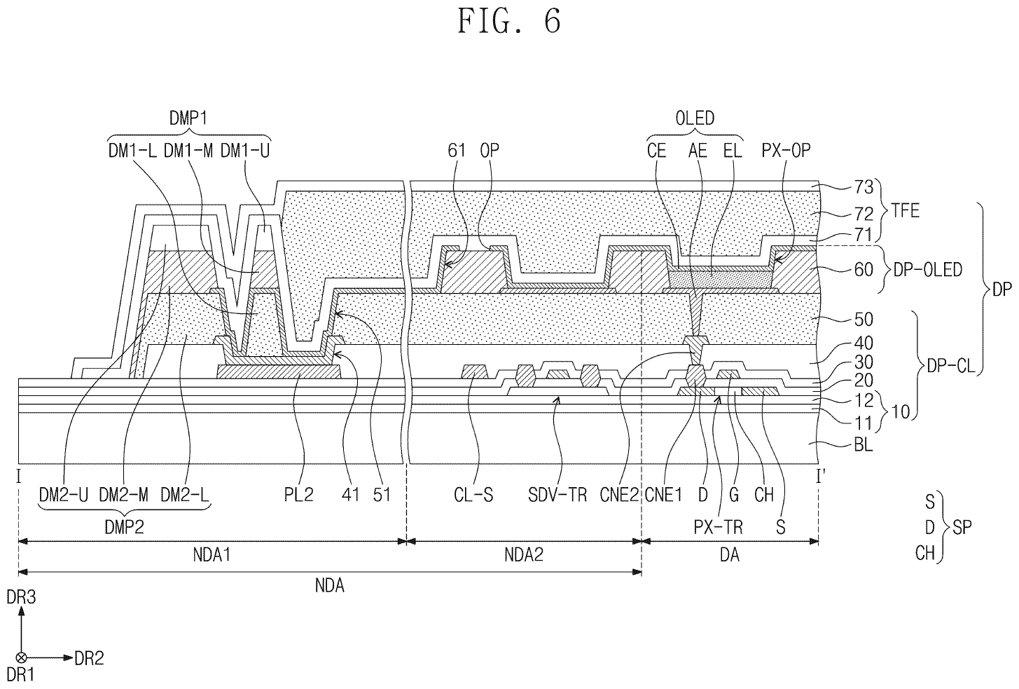

FIG. 6 is a cross-sectional view of the display panel taken along the line I-I′ of FIG. 4, according to some embodiments of the inventive concept.

Referring to FIG. 6, a display panel DP includes a base layer BL, a circuit layer DP-CL, a display element layer DP-OLED, and an encapsulation layer TFE. In some embodiments, the base layer BL, the circuit layer DP-CL, the display element layer DP-OLED, and the encapsulation layer TFE may be sequentially stacked in a third direction DR3, which may be perpendicular to the first and second directions DR1 and DR2.

The base layer BL may be a member for providing a base surface on which the circuit layer DP-CL is disposed. The base layer BL may be a glass substrate, a metal substrate, a plastic substrate, or the like. However, some embodiments of the inventive concept is not limited thereto, and the base layer BL may be an inorganic layer, an organic layer, or a composite material layer.

The circuit layer DP-CL is disposed on the base layer BL. The circuit layer DP-CL may include the transistors T1 to T7 (see, e.g., FIG. 5), the capacitor CAP (see, e.g., FIG. 5), and the like. FIG. 6 illustrates only one transistor PX-TR (hereinafter, referred to as a pixel transistor) for ease of explanation. In some embodiments, the pixel transistor PX-TR may be the sixth transistor T6 described with reference to FIG. 5.

The circuit layer DP-CL may further include first to fifth insulation layers 10, 20, 30, 40, and 50, which are stacked in the third direction DR3. The first insulation layer 10 may be disposed on the base layer BL. The first insulation layer 10 may include a barrier layer 11 and a buffer layer 12.

The barrier layer 11 may include an inorganic material. The barrier layer 11 may prevent oxygen or moisture, which is introduced through the base layer BL, from infiltrating into the pixels PX (see, e.g., FIG. 4) or substantially reduce infiltration thereof. The buffer layer 12 may include an inorganic material. The buffer layer 12 may provide surface energy, which is lower than that of the base layer BL, to the pixels PX so that the pixels PX are stably formed on the base layer BL. In FIG. 6, the barrier layer 11 and the buffer layer 12 are each illustrated as a single layer. However, this is exemplarily illustrated, and according to some embodiments a plurality of barrier layers 11 and buffer layers 12 may be provided and alternately stacked. In some examples, at least any one among the barrier layer 11 and the buffer layer 12 may be provided in plural form or may be omitted.

The pixel transistor PX-TR may be disposed on the first insulation layer 10. The pixel transistor PX-TR may include a semiconductor pattern SP and a gate G. The semiconductor pattern SP may be disposed on the first insulation layer 10. The semiconductor pattern SP may include a semiconductor material. The semiconductor pattern SP may include a channel region CH, a source S, and a drain D. The semiconductor pattern SP may be covered by the second insulation layer 20, and the gate G may be disposed on the second insulation layer 20. The gate G may be disposed on the second insulation layer 20 so as to correspond to (e.g., overlap) the channel region CH of the semiconductor pattern SP. That is, the gate G and the channel region CH of the semiconductor pattern SP may be spaced apart from each other by the second insulation layer 20. The gate G may be connected to one electrode of the capacitor CAP (see, e.g., FIG. 5).

The source S and the drain D of the semiconductor pattern SP may be spaced apart from each other with the channel region CH therebetween. The source S of the semiconductor pattern SP may be used as an input electrode of the pixel transistor PX-TR, and the drain D of the semiconductor pattern SP may be used as an output electrode of the pixel transistor PX-TR.

The third insulation layer 30 is disposed on the gate G and the second insulation layer 20. In the second and third insulation layers 20 and 30, a contact hole may be provided so as to expose the drain D of the semiconductor pattern SP. A first connection electrode CNE1, which is connected to the drain D via the contact hole, may be disposed on the third insulation layer 30. In some other embodiments of the inventive concept, the pixel transistor PX-TR in FIG. 6 may further include an input electrode and an output electrode, which are respectively connected to the source S and the drain D of the semiconductor pattern SP.

The fourth insulation layer 40 is disposed on the third insulation layer 30. The fourth insulation layer 40 may include an organic material and/or an inorganic material, and may have a single-layer structure or a stacked structure. The pixel transistor PX-TR according to some embodiments of the inventive concept may be formed to have various suitable structures, and is not limited to the embodiments illustrated in FIG. 6.

A second connection electrode CNE2 may be disposed on the fourth insulation layer 40. The second connection electrode CNE2 may be connected to the first connection electrode CNE1. The fifth insulation layer 50 may be disposed on the second connection electrode CNE2.

The scan driver SDV (see, e.g., FIG. 4), which is connected to the first to third scan lines GWi, GCi, and Gli (see, e.g., FIG. 5) of the pixels PX (see, e.g., FIG. 4), may be disposed between a second power supply line PL2 and a display region DA. The second power supply line PL2 may be disposed at the outside of the scan driver SDV. Here, the language “disposed at the outside” means that the second power supply line PL2 may be disposed farther away from the display region DA than the scan driver SDV. The scan driver SDV may include drive transistors SDV-TR. A scan clock line CL-S may be electrically connected to the drive transistors SDV-TR. The drive transistors SDV-TR may receive, from the scan clock line CL-S, clock signals that are applied from a timing controller. FIG. 6 exemplarily illustrates one scan clock line CL-S, but the number of the scan clock lines CL-S is not limited thereto and may thus be two or more. Accordingly, the drive transistors SDV-TR may receive two or more clock signals.

The display element layer DP-OLED is disposed on the circuit layer DP-CL. The display element layer DP-OLED may include a plurality of light-emitting elements and a sixth insulation layer 60. FIG. 6 illustrates only one light-emitting element OLED for convenience of explanation.

The light-emitting element OLED is disposed on the fifth insulation layer 50. The light-emitting element OLED may include a first electrode AE, a light-emitting layer (or intermediate layer) EL, and a second electrode CE. The first electrode AE may pass through the fifth insulation layer 50 and may be electrically connected to the pixel transistor PX-TR via the second connection electrode CNE2.

The sixth insulation layer 60 may be disposed on the fifth insulation layer 50. A pixel opening PX-OP may be defined in the sixth insulation layer 60, and the pixel opening PX-OP may expose at least a portion of the first electrode AE. The sixth insulation layer 60 may be a pixel-defining film.

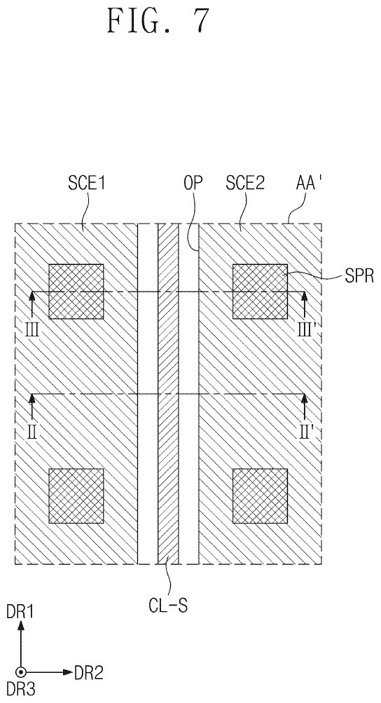

The light-emitting layer EL may be disposed on the first electrode AE, which is exposed by the pixel opening PX-OP defined in the sixth insulation layer 60. The light-emitting layer EL may include a light-emitting material. For example, the light-emitting layer EL may be composed of at least one of materials that emit red, green, or blue light. The light-emitting layer EL may include a fluorescent material or a phosphorescent material. The light-emitting layer EL may include an organic light-emitting material or an inorganic light-emitting material. The light-emitting layer EL may emit light in response to a potential difference between the first electrode AE and the second electrode CE. The light-emitting layer EL may further include a functional layer FNL (see, e.g., FIG. 7). The functional layer FNL may include a hole injection/transport material and/or an electron injection/transport material.

The second electrode CE may be disposed on the light-emitting layer EL. The second electrode CE may be provided to the pixels PX (see, e.g., FIG. 4) in common (i.e., the second electrode CE may be common to all of, and shared by, the pixels PX). The second electrode CE may be electrically connected to the second power supply line PL2 disposed in a non-display region NDA.

According to some embodiments of the inventive concept, an opening (or first opening) OP may be defined in the second electrode CE. The opening OP may overlap the scan clock line CL-S in a plan view. A width of the opening OP may be greater than a width of the scan clock line CL-S. The second electrode CE may not overlap the scan clock line CL-S in a plan view, and thus the capacitance between the second electrode CE and the scan clock line CL-S may be lowered. As a result, the power consumption of the display device DD (see, e.g., FIG. 1) according to the inventive concept may be reduced. The opening OP will be described in further detail below.

The non-display region NDA may be divided into a first non-display region NDA1 and a second non-display region NDA2. The second power supply line PL2 may be disposed in the first non-display region NDA1, and the opening OP may be disposed in the second non-display region NDA2.

In some examples of the inventive concept, the second power supply line PL2 and the first connection electrode CNE1 are disposed on (e.g., at) the same layer. When the pixel transistor PX-TR includes input and output electrodes, the second power supply line PL2 are disposed on (e.g., at) the same layer as the input and output electrodes of the pixel transistor PX-TR. First and second contact parts 41 and 51 for exposing the second power supply line PL2 are respectively provided in the fourth and fifth insulation layers 40 and 50. The first and second contact parts 41 and 51 may be defined as open regions, corresponding to the second power supply line PL2, of the fourth and fifth insulation layers 40 and 50.

The second electrode CE may receive the second driving voltage ELVSS (see, e.g., FIG. 5) from the second power supply line PL2. However, some embodiments of the inventive concept is not limited thereto, and the display panel DP according to the inventive concept may further include a bridge electrode between the second power supply line PL2 and the second electrode CE. That is, the second electrode CE may receive the second driving voltage ELVSS from the second power supply line PL2 via the bridge electrode.

The encapsulation layer TFE may be disposed on the display element layer DP-OLED to encapsulate the light-emitting element OLED. The encapsulation layer TFE may entirely cover the display region DA. The encapsulation layer TFE may partially cover the non-display region NDA.

The encapsulation layer TFE may include a first inorganic layer 71, an organic layer 72, and a second inorganic layer 73, which are sequentially stacked along the third direction DR3. In some embodiments, the first inorganic layer 71, the organic layer 72, and the second inorganic layer 73 are each illustrated as a single layer. However, this is exemplarily illustrated, and at least any one among the first inorganic layer 71, the organic layer 72, and the second inorganic layer 73 may be provided in plural form or may be omitted. However, embodiments of the inventive concept are not limited thereto

The first inorganic layer 71 may cover the second electrode CE. The first inorganic layer 71 may prevent or substantially reduce likelihood of moisture or oxygen from infiltrating into the light-emitting element OLED from the outside. For example, the first inorganic layer 71 may include silicon nitride, silicon oxide, or a compound formed through combination thereof. The first inorganic layer 71 may be formed through a deposition process.

The organic layer 72 may be disposed on the first inorganic layer 71 to be in contact with the first inorganic layer 71. The organic layer 72 may provide a flat surface on the first inorganic layer 71. For example, the organic layer 72 may provide a flat surface.

Uneven portions formed on an upper surface of the first inorganic layer 71 or particles present on the first inorganic layer 71 may be covered by the organic layer 72, thereby preventing a surface condition of the upper surface of the first inorganic layer 71 from affecting components to be formed on the organic layer 72 or substantially reducing the effect thereof. In addition, the organic layer 72 may relieve stress between contacting layers. The organic layer 72 may include an organic material, and may be formed through a solution process such as spin coating, slit coating, an inkjet process, and/or the like.

The second inorganic layer 73 is disposed on the organic layer 72 to cover the organic layer 72. The second inorganic layer 73 may be stably formed on a relatively flat surface compared to the case of being disposed on top of the first inorganic layer 71. The second inorganic layer 73 may seal moisture, or the like released from the organic layer 72, and prevent the moisture from flowing out to the outside or substantially reduce likelihood thereof. The second inorganic layer 73 may include silicon nitride, silicon oxide, or a compound formed through combination thereof. The second inorganic layer 73 may be formed through a deposition process.

The display panel DP may further include first and second dam parts DMP1 and DMP2, which are disposed in the first non-display region NDA1. The first and second dam parts DMP1 and DMP2 may each have a multi-layered structure. The second dam part DMP2 may be disposed at the outside of the first dam part DMP1. The first dam part DMP1 includes a first lower dam DM1-L, a first middle dam DM1-M, and a first upper dam DM1-U. The second dam part DMP2 may include a second lower dam DM2-L, a second middle dam DM2-M, and a second upper dam DM2-U.

The first and second lower dams DM1-L and DM2-L may be concurrently (e.g., simultaneously) formed with the fifth insulation layer 50. The first and second middle dams DM1-M and DM2-M may be respectively provided on the first and second lower dams DM1-L and DM2-L. The first and second middle dams DM1-M and DM2-M may be concurrently (e.g., simultaneously) formed with the sixth insulation layer 60. The first and second upper dams DM1-U and DM2-U may be respectively provided on the first and second middle dams DM1-M and DM2-M.

The first and second dam parts DMP1 and DMP2 may be provided in a closed-loop shape to surround the display region DA, in the first non-display region NDA1. Accordingly, the first and second dam parts DMP1 and DMP2 may prevent liquid organic material from spreading outward during a process of forming the organic layer 72 of the encapsulation layer TFE. The organic layer 72 may be formed by coating the first inorganic layer 71 with the liquid organic material through an inkjet process. Here, the first and second dam parts DMP1 and DMP2 may set a boundary of a region in which the liquid organic material is disposed.

In some examples of the inventive concept, the first dam part DMP1 may partially overlap the second power supply line PL2. FIG. 6 illustrates a structure having the two dam parts DMP1 and DMP2; however, embodiments of the inventive concept are not limited thereto. That is, the display panel DP may be provided with only one dam part among the first and second dam parts DMP1 and DMP2. In addition, FIG. 6 illustrates a structure in which the first and second dam parts DMP1 and DMP2 are disposed spaced apart from each other, but some embodiments of the inventive concept is not limited thereto. For example, the first and second dam parts DMP1 and DMP2 may be connected to each other. In addition, it is illustrated that the first and second dam parts DMP1 and DMP2 each have a triple-layer structure, but the first and second dam parts DMP1 and DMP2 may each have a double-layer structure.

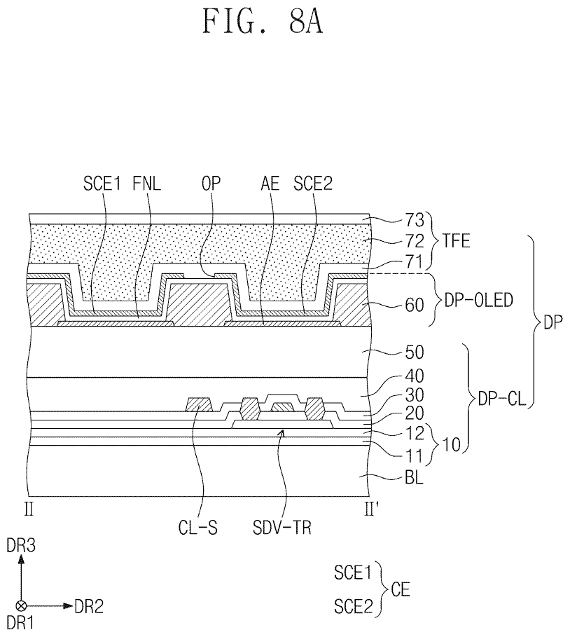

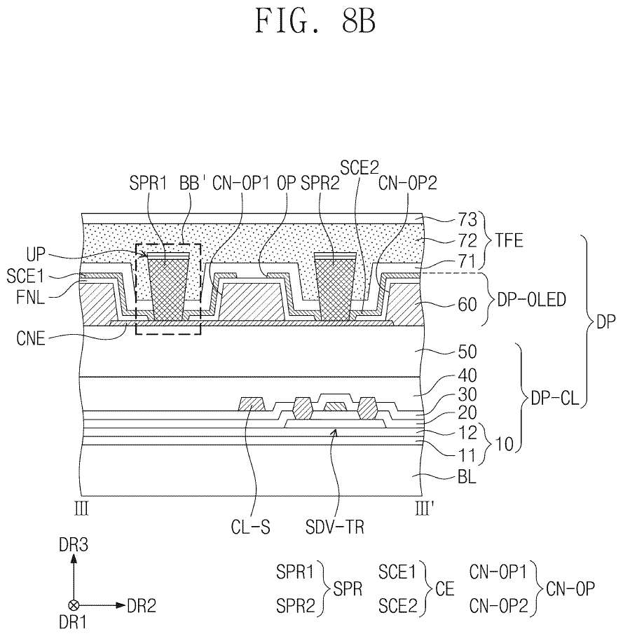

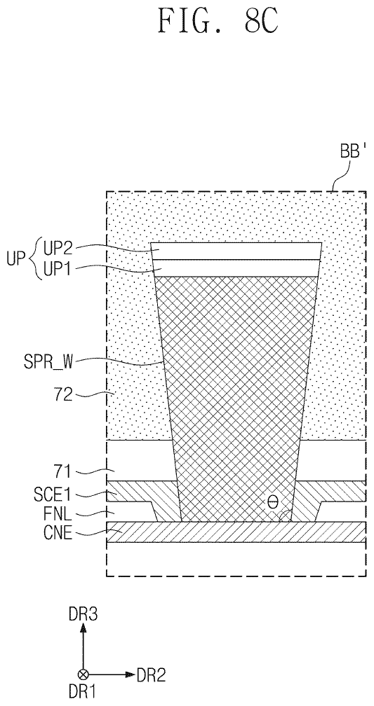

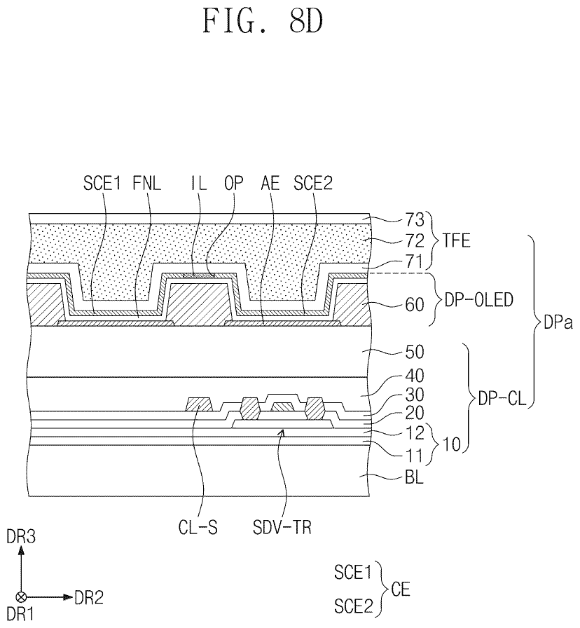

FIG. 7 is an enlarged view of the region AA′ illustrated in FIG. 4, according to some embodiments of the inventive concept. FIG. 8A is a cross-sectional view of the display panel taken along the line II-II′ of FIG. 7, according to some embodiments of the inventive concept. FIG. 8B is a cross-sectional view of the display panel taken along the line III-III′ of FIG. 7, according to some embodiments of the inventive concept. FIG. 8C is an enlarged view of the region BB′ illustrated in FIG. 7, according to some embodiments of the inventive concept. FIG. 8D is a cross-sectional view of a display panel according to some other embodiments of the inventive concept. Hereinafter, in the description of FIGS. 7 to 8D, the components described with reference to FIG. 6 will be denoted as the same reference numerals or symbols and description thereof will be omitted.

Referring to FIG. 7, a second electrode CE may include a first sub-electrode SCE1 and a second sub-electrode SCE2, which are spaced apart from each other with respect to an opening OP. The first sub-electrode SCE1 and the second sub-electrode SCE2 may be spaced apart from each other in the second direction DR2. The first sub-electrode SCE1 and the second sub-electrode SCE2 may be electrically connected to each other through a separator SPR. In some examples, a plurality of separators SPR may be provided. The separators SPR may be arranged in the first direction DR1. However, embodiments of the inventive concept are not limited thereto, and the separators SPR may, for example, be arranged in a grid shape.

Referring to FIGS. 7 and 8A together, a functional layer FNL may be disposed between a first electrode AE and the second electrode CE. A light-emitting element OLED according to the inventive concept may include a functional layer FNL. The functional layer FNL may control transfer of electric charges between the first electrode AE and the second electrode CE. The functional layer FNL may include a hole injection/transport material and/or an electron injection/transport material. The functional layer FNL may include at least one of an electron blocking layer, a hole transport layer, a hole injection layer, a hole blocking layer, an electron transport layer, an electron injection layer, or a charge generation layer. The first electrode AE illustrated in FIG. 8A may be a metal layer which is not connected to a transistor, or the like. In some examples, the first electrode AE may be omitted.

Referring to FIGS. 7 and 8B together, a display panel DP according to the inventive concept may further include a connection electrode CNE that electrically connects the first sub-electrode SCE1 and the second sub-electrode SCE2 to each other. The connection electrode CNE according to the inventive concept may be disposed on (e.g., at) the same layer as the first electrode AE illustrated in FIG. 8B. However, some embodiments of the inventive concept is not limited thereto, and the connection electrode CNE and the first electrode AE may be disposed on different layers.

A contact opening CN-OP may be defined in a sixth insulation layer 60, and the contact opening CN-OP may expose at least a portion of the connection electrode CNE. In some examples, a plurality of contact openings CN-OP may be provided. The contact opening CN-OP may correspond to the pixel opening PX-OP illustrated in FIG. 6. The contact opening CN-OP may include a first contact opening CN-OP1 and a second contact opening CN-OP2, which are spaced apart from each other with respect to the opening OP.

The display panel DP according to the inventive concept may further include a separator SPR disposed in the contact opening CN-OP. The separator SPR may be disposed on the connection electrode CNE. The separator SPR may include an insulating material, and particularly include an organic insulating material. The separator SPR may also include an inorganic insulating material, and may be composed of multiple layers of the organic insulating material and the inorganic insulating material. In some examples, the separator may include a conductive material.

The separator SPR may include a first separator SPR1 and a second separator SPR2 which are spaced apart from each other in the second direction DR2. The first separator SPR1 and the second separator SPR2 may have the same shape. The first separator SPR1 and the second separator SPR2 may be respectively disposed in the first contact opening CN-OP1 and the second contact opening CN-OP2, and thus disposed on the connection electrode CNE. The first sub-electrode SCE1 and the second sub-electrode SCE2 according to the inventive concept may be electrically connected to each other through the first and second separators SPR1 and SPR2. The separator SPR will be described in further detail with reference to 8C.

Referring to FIGS. 8B and 8C together, the separator SPR may have a reverse-tapered shape. That is, an angle θ (hereinafter, taper angle) between a side surface SPR_W of the separator SPR and an upper surface of a pixel-defining film PDL may be an obtuse angle. However, this is exemplarily illustrated, and the taper angle θ may be set in various ways. In addition, the separator SPR may have a structure such as a tip-portion; however, embodiments of the inventive concept are not limited thereto.

The first sub-electrode SCE1 and the second sub-electrode SCE2 may each be in contact with the connection electrode CNE through the separator SPR. A lower surface of the first sub-electrode SCE1 and a lower surface of the second sub-electrode SCE2 may each be in contact with an upper surface of the connection electrode CNE.

The first sub-electrode SCE1 and the second sub-electrode SCE2 may be disposed between the functional layer FNL and the separator SPR by adjusting deposition locations of the first sub-electrode SCE1 and the second sub-electrode SCE2, and thus the first sub-electrode SCE1 and the second sub-electrode SCE2 may each be in direct contact with the connection electrode CNE. As a result, even when the first sub-electrode SCE1 and the second sub-electrode SCE2 are disposed spaced apart from each other by the opening OP, the first sub-electrode SCE1 and the second sub-electrode SCE2 may each be electrically connected to the connection electrode CNE, so that the first sub-electrode SCE1 and the second sub-electrode SCE2 may be electrically connected to each other. A region in which the first sub-electrode SCE1 is in contact with the connection electrode CNE may be defined as a first contact region, and a region in which the second sub-electrode SCE2 is in contact with the connection electrode CNE may be defined as a second contact region.

Referring to FIG. 8C, a dummy layer UP may be disposed on the separator SPR. The dummy layer UP may include a first dummy layer UP1 disposed on the separator SPR and a second dummy layer UP2 disposed on the first dummy layer UP1. The first dummy layer UP1 and the functional layer FNL may be formed through the same process and may include the same material. The second dummy layer UP2 and the second electrode CE may be formed through the same process and may include the same material. That is, the first dummy layer UP1 and the second dummy layer UP2 may be respectively and concurrently (e.g., simultaneously) formed during the process of forming the functional layer FNL and the second electrode CE. In some other embodiments, the display panel DP may not include the dummy layer UP.

Referring to FIG. 8D, a display panel Dpa according to the inventive concept may further include an insulation layer IL. According to some embodiments of the inventive concept, the insulation layer IL may be formed in an opening OP. The insulation layer IL may include an organic material and/or an inorganic material, and may have a single-layer structure or a stacked structure. For example, the inorganic material may include silicon nitride, silicon oxide, or a compound formed through combination thereof. Because the insulation layer IL is formed in the opening OP before the second electrode CE is formed, the second electrode CE may not be formed in the opening OP. As a result, the second electrode CE may not overlap the scan clock line CL-S in a plan view, and thus the capacitance between the second electrode CE and the scan clock line CL-S may be lowered. Therefore, the power consumption of the display device DD (see, e.g., FIG. 1) according to the inventive concept may be reduced.

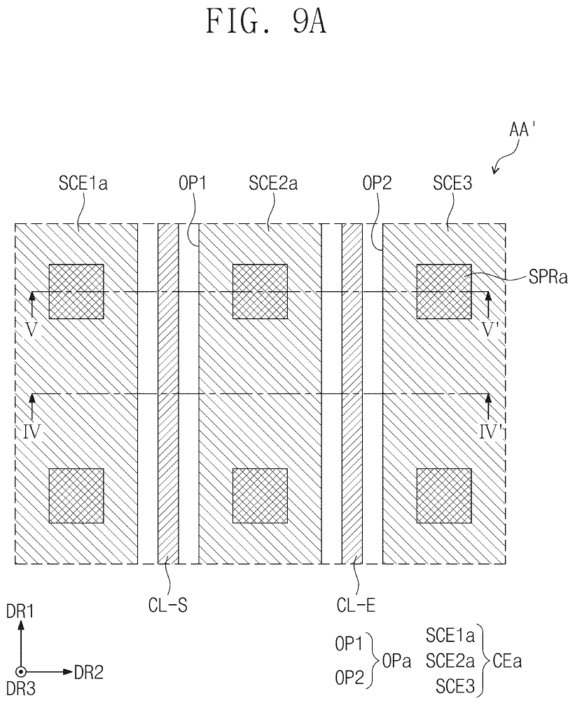

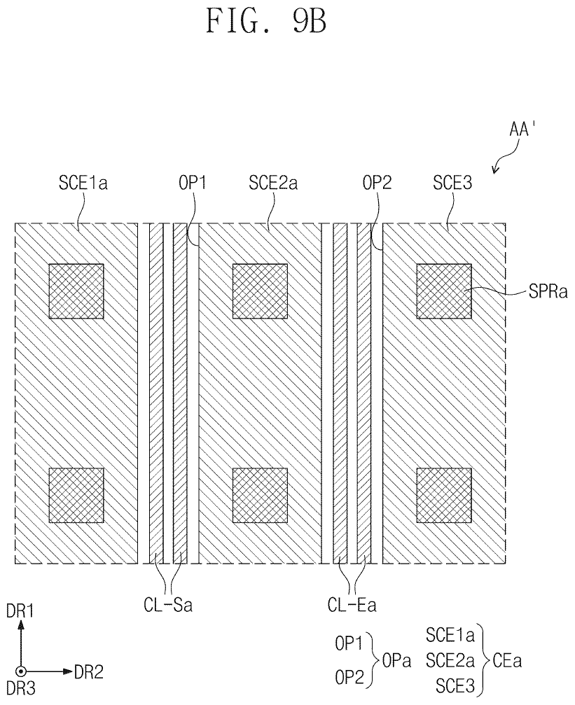

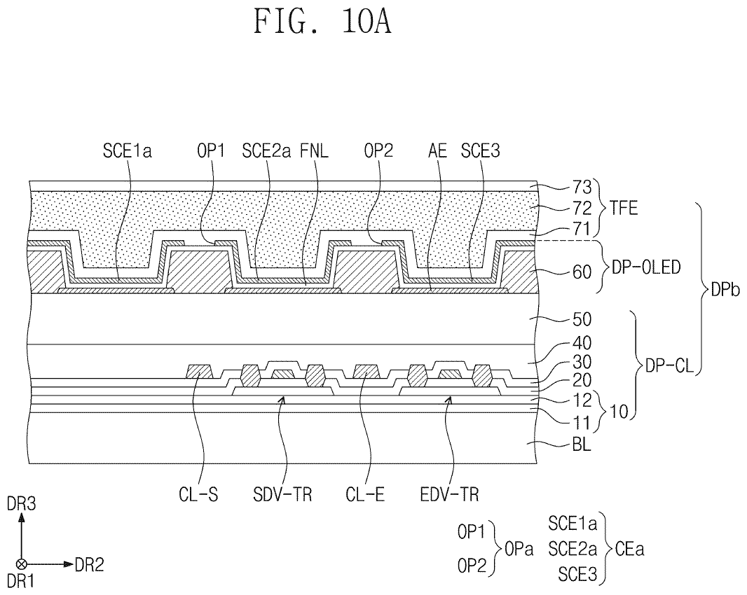

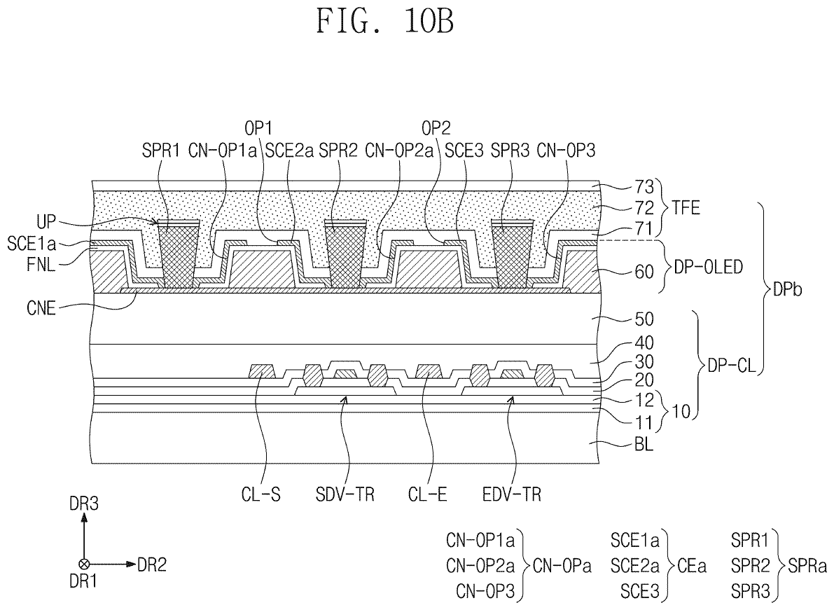

FIGS. 9A and 9B are enlarged views of a portion of a display panel according to some embodiments of the inventive concept. For example, FIGS. 9A and 9B are enlarged views of the region AA′ illustrated in FIG. 4. FIG. 10A is a cross-sectional view of the display panel taken along the line IV-IV′ of FIG. 9A, according to some embodiments of the inventive concept. FIG. 10B is a cross-sectional view of the display panel taken along the line V-V′ of FIG. 9A, according to some embodiments of the inventive concept. Hereinafter, a duplicate explanation of the content previously described may be omitted.

Referring to FIGS. 9A and 10A together, an opening Opa may be defined in a second electrode Cea. The opening Opa may include a first opening OP1 and a second opening OP2. The first opening OP1 may correspond to the opening OP illustrated in FIG. 7.

The second electrode Cea may include a first sub-electrode SCE1a, a second sub-electrode SCE2a, and a third sub-electrode SCE3. The first sub-electrode SCE1a and the second sub-electrode SCE2a may be spaced apart from each other with respect to the first opening OP1. The second sub-electrode SCE2a and the third sub-electrode SCE3 may be spaced apart from each other with respect to the second opening OP2. The first sub-electrode SCE1a, the second sub-electrode SCE2a, and the third sub-electrode SCE3 may be electrically connected to each other through separators SPRa. In some examples, a plurality of separators SPRa may be provided. The separators SPRa may be arranged in the second direction DR2. However, some embodiments of the inventive concept is not limited thereto, and the separators SPRa may be arranged in a grid shape.

A scan clock line CL-S and an emission clock line CL-E may each extend in the first direction DR1. The scan clock line CL-S may overlap the first opening OP1 in a plan view, and the emission clock line CL-E may overlap the second opening OP2 in a plan view. The opening OP may overlap the scan clock line CL-S in a plan view. A width of the first opening OP1 in the second direction DR2 may be greater than a width of the scan clock line CL-S in the second direction DR2. A width of the second opening OP2 in the second direction DR2 may be greater than a width of the emission clock line CL-E in the second direction DR2.

The second electrode Cea may not overlap the scan clock line CL-S in a plan view, and therefore the capacitance between the second electrode Cea and the scan clock line CL-S may be lowered. The second electrode Cea may not overlap the emission clock line CL-E in a plan view, and therefore the capacitance between the second electrode Cea and the emission clock line CL-E may be lowered. As a result, the power consumption of the display device DD (see, e.g., FIG. 1) according to the inventive concept may be reduced.

Referring to FIG. 9B, the number of scan clock lines CL-Sa and the number of emission clock lines CL-Ea may each be two. The scan clock lines CL-Sa and the emission clock lines CL-Ea may each extend in the first direction DR1. The scan clock lines CL-Sa may transmit first and second clock signals to the scan driver SDV (see, e.g., FIG. 4) from a timing controller, and the emission clock lines CL-Ea may transmit third and fourth clock signals to the emission driver EDV (see, e.g., FIG. 4). The scan clock lines CL-Sa may be disposed in the first opening OP1, and the emission clock lines CL-Ea may be disposed in the second opening OP2.

Referring to FIGS. 9A and 10B together, a display panel DPb according to the inventive concept may further include a connection electrode CNE which electrically connects the first sub-electrode SCE1a, the second sub-electrode SCE2a, and the third sub-electrode SCE3 to each other. The connection electrode CNE according to the inventive concept may be disposed on (e.g., at) the same layer as the first electrode AE illustrated in 10A. However, embodiments of the inventive concept are not limited thereto, and the connection electrode CNE and the first electrode AE may be disposed on different layers.

A contact opening CN-Opa may be defined in a sixth insulation layer 60, and the contact opening CN-Opa may expose at least a portion of the connection electrode CNE. In some examples, a plurality of contact openings CN-Opa may be provided. The contact opening CN-Opa may include a first contact opening CN-OP1a, a second contact opening CN-OP2a, and a third contact opening CN-OP3. The first contact opening CN-OP1a and the second contact opening CN-OP2a may be spaced apart from each other with respect to the first opening OP1, and the second contact opening CN-OP2a and the third contact opening CN-OP3 may be spaced apart from each other with respect to the second opening OP2.

The separator SPRa may include a first separator SPR1, a second separator SPR2, and a third separator SPR3. The first separator SPR1, the second separator SPR2, and the third separator SPR3 may have the same shape. The first separator SPR1, the second separator SPR2, and the third separator SPR3 may be respectively disposed in the first contact opening CN-OP1a, the second contact opening CN-OP2a, and the third contact opening CN-OP3, and thus disposed on the connection electrode CNE. The first sub-electrode SCE1a, the second sub-electrode SCE2a, and the third sub-electrode SCE3 according to the inventive concept may be electrically connected to each other through the first to third separators SPR1, SPR2, and SPR3. The insulation layer IL (see, e.g., FIG. 8D) may be formed in each of the first opening OP1 and the second opening OP2.

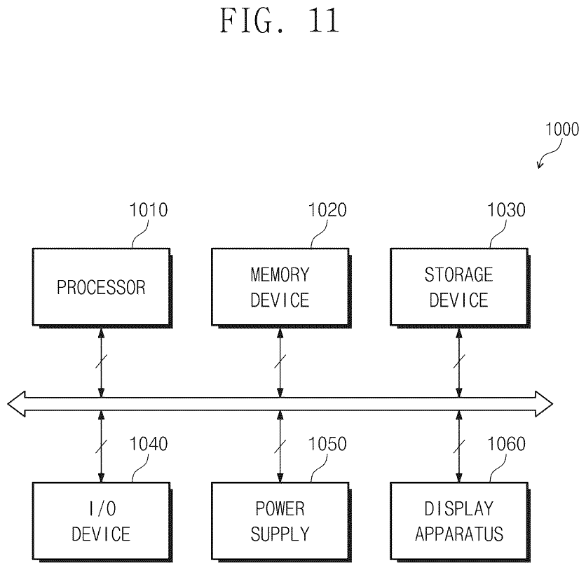

FIG. 11 is a block diagram illustrating an electronic device 1000 according to some embodiments of the inventive concept.

Referring to FIGS. 11 and 1, in an embodiment, an electronic device 1000 may include a processor 1010, a memory device 1020, a storage device 1030, an input/output (“I/O”) device 1040, a power supply 1050, and a display device 1060. Here, the display device 1060 may correspond to the display device DD of FIG. 1. The electronic device 1000 may further include a plurality of ports for communicating with a video card, a sound card, a memory card, a universal serial bus (“USB”) device, or the like. In an embodiment, the electronic device 1000 may be implemented as a television. In another embodiment, the electronic device 1000 may be implemented as a smart phone. However, embodiments are not limited thereto, in another embodiment, the electronic device 1000 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 1010 may perform various computing functions. In an embodiment, the processor 1010 may be a microprocessor, a central processing unit (“CPU”), an application processor (“AP”), or the like. The processor 1010 may be coupled to other components via an address bus, a control bus, a data bus, or the like. In an embodiment, the processor 1010 may be coupled to an extended bus such as a peripheral component interconnection (“PCI”) bus.

The memory device 1020 may store data for operations of the electronic device 1000. In an embodiment, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 1030 may include a solid state drive (“SSD”) device, a hard disk drive (“HDD”) device, a CD-ROM device, or the like. In an embodiment, the I/O device 1040 may include an input device such as a keyboard, a keypad, a mouse device, a touchpad, a touch-screen, or the like, and an output device such as a printer, a speaker, or the like.

The power supply 1050 may provide power for operations of the electronic device 1000. The power supply 1050 may provide power to the display device 1060. The display device 1060 may be coupled to other components via the buses or other communication links. In an embodiment, the display device 1060 may be included in the I/O device 1040.

In an embodiment the electronic device may be implemented as a smartphone. However the embodiments of the present disclosure may be exemplary and may not be limited to this. For example, the electronic device 1000 may be implemented as a mobile phone, a video phone, a smart pad, a smart watch, a television, a home appliance, a tablet PC, a vehicle display, a computer monitor, a notebook computer, an entertainment device like a head-mounted display device, etc. In addition, the electronic device 1000 may be a television, a monitor, a notebook computer, or a tablet. In addition, the electronic device 1000 may be a car.

The display device according to the embodiments may be applied to a device included in a computer, a notebook, a mobile phone, a smartphone, a smart pad, a PMP, a PDA, an MP3 player, or the like.

An opening may be defined in a cathode of a display device according to the inventive concept. In a plan view, the opening may overlap a scan clock line disposed in a non-display region. When the display device is driven, the cathode may not overlap the scan clock line in a plan view, and therefore the capacitance between the cathode and the scan clock line may be lowered. As a result, the power consumption of the display device according to the inventive concept may be reduced.

In the above, description has been made with reference to embodiments, but those skilled in the art or those of ordinary skill in the relevant technical field may understand that various modifications and changes may be made to the inventive concept within the scope not departing from the spirit and the technology scope of the inventive concept described in the claims to be described later.

Therefore, the technical scope of the inventive concept is not limited to the contents described in the detailed description of the specification, but should be determined by the claims and their equivalents.

What is claimed is:

1. A display device comprising:
a base layer in which a display region and a non-display region adjacent to the display region are defined;
a circuit layer comprising a scan clock line in the non-display region and extending in a first direction, and a scan driver connected to the scan clock line; and
a light-emitting element on the circuit layer, and comprising a first electrode, an intermediate layer on the first electrode, and a second electrode on the intermediate layer,
wherein a first opening overlapping the scan clock line is defined in the second electrode.

2. The display device of claim 1, wherein the second electrode comprises a first sub-electrode and a second sub-electrode that are spaced apart from each other with respect to the first opening.

3. The display device of claim 2, further comprising a connection electrode configured to electrically connect the first sub-electrode and the second sub-electrode to each other,
wherein the first sub-electrode and the second sub-electrode each are in contact with the connection electrode.

4. The display device of claim 3, further comprising:
an insulation film in which a contact opening that exposes at least a portion of the connection electrode is defined; and
a separator in the contact opening.

5. The display device of claim 4, wherein the contact opening comprises a first contact opening and a second contact opening that are spaced apart from each other with respect to the first opening, and
wherein the separator comprises a first separator in the first contact opening, and a second separator in the second contact opening.

6. The display device of claim 5, wherein in a first contact region adjacent to the first separator, a lower surface of the first sub-electrode is in contact with an upper surface of the connection electrode, and
wherein in a second contact region adjacent to the second separator, a lower surface of the second sub-electrode is in contact with the upper surface of the connection electrode.

7. The display device of claim 5, wherein the first separator and the second separator each are provided in plural form, and
wherein the first separators and the second separators are each arranged in the first direction.

8. The display device of claim 3, wherein the connection electrode and the first electrode are on a same layer.

9. The display device of claim 1, wherein the circuit layer further comprises an emission clock line in the non-display region and extending in the first direction, and an emission driver connected to the emission clock line.

10. The display device of claim 9, wherein a second opening overlapping the emission clock line is defined in the second electrode, and
wherein the first opening and the second opening are spaced apart from each other in a second direction crossing the first direction.

11. The display device of claim 9, wherein the emission driver and the scan driver are spaced apart from each other with respect to the display region.

12. The display device of claim 10, further comprising an insulation layer in each of the first opening and the second opening.

13. The display device of claim 1, further comprising a power supply line in the non-display region, and configured to apply a driving voltage to the second electrode.

14. The display device of claim 13, wherein the non-display region comprises a first non-display region in which the power supply line is, and a second non-display region in which the first opening is positioned, and
wherein the second non-display region is between the first non-display region and the display region.

15. A display device comprising:
a circuit layer comprising a scan clock line configured to apply a clock signal and a scan driver connected to the scan clock line;
a light-emitting element on the circuit layer, and comprising a first electrode, an intermediate layer on the first electrode, and a second electrode having a first sub-electrode and a second sub-electrode spaced apart from each other with respect to an opening that is defined overlapping the scan clock line; and
a connection electrode configured to electrically connect the first sub-electrode and the second sub-electrode to each other,
wherein the connection electrode and the first electrode are on a same layer.

16. The display device of claim 15, further comprising:
an insulation film in which a contact opening that exposes at least a portion of the connection electrode is defined; and
a separator in the contact opening.

17. The display device of claim 16, wherein the contact opening comprises a first contact opening and a second contact opening which are spaced apart from each other with respect to the opening, and
wherein the separator comprises a first separator in the first contact opening, and a second separator in the second contact opening.

18. The display device of claim 17, wherein in a first contact region adjacent to the first separator, a lower surface of the first sub-electrode is in contact with an upper surface of the connection electrode, and
wherein in a second contact region adjacent to the second separator, a lower surface of the second sub-electrode is in contact with an upper surface of the connection electrode.

19. The display device of claim 15, wherein the scan clock line extends in a first direction, and the opening is defined to be parallel to the scan clock line in the first direction.

20. An electronic device comprising:
a display device configured to display an image; and
a processor configured to control the display device to display the image,
wherein the display device comprises:
a base layer in which a display region and a non-display region adjacent to the display region are defined;
a circuit layer comprising a scan clock line in the non-display region and extending in a first direction, and a scan driver connected to the scan clock line; and
a light-emitting element on the circuit layer, and comprising a first electrode, an intermediate layer on the first electrode, and a second electrode on the intermediate layer,
wherein a first opening overlapping the scan clock line is defined in the second electrode.
